(19) United States
(12) Patent Application Publication
(10) Pub. No.: US 2019/0006438 A1
(43) Pub. Date: Jan. 3, 2019

(54) ORGANIC LIGHT-EMITTING DIODE DISPLAY PANEL AND ELECTRONIC DEVICE

(71) Applicant: Lenovo (Beijing) Co., Ltd., Beijing (CN)

(72) Inventors: Hailong WU, Beijing (CN); Nan LIN, Beijing (CN)

(21) Appl. No.: 15/918,501

(22) Filed: Mar. 12, 2018

(30) Foreign Application Priority Data
Jun. 30, 2017 (CN) 201710524398.2

(51) Int. Cl. H01L 27/32

(52) U.S. Cl. CPC H01L 27/3225; H01L 27/3211; H01L 27/3244

(57) ABSTRACT

An organic light-emitting diode (OLED) display panel includes a layered structure. The layered structure includes an emitter and a receiver. The emitter emits an infrared light, and the infrared light traverses a portion of the layered structure that is above the emitter, and the receiver receives the infrared light that traverses a portion of the layered structure that is above the receiver.

### CROSS-REFERENCES TO RELATED APPLICATION

This application claims priority to Chinese Patent Application No. 201710524398.2, filed on Jun. 30, 2017, the entire contents of which are hereby incorporated by reference.

### TECHNICAL FIELD

The present disclosure generally relates to the technical field of display device and, more particularly, to an organic light-emitting diode (OLED) display panel and an electronic device containing the same.

### BACKGROUND

Organic light-emitting diode (OLED) display panel has various advantages such as self-illumination, wide viewing angle, and quick response. Thus, the OLED display panel possesses application potential in the field of flat plane display, and is considered to represent the new-generation flat plane display products and technologies succeeding the liquid crystal display (LCD) panel and plasma display panel (PDP).

The conventional electronic device that adopts an OLED display panel often uses the OLED display panel as an individual display panel to replace the traditional LED display panel. The conventional electronic device often further includes an individual proximity sensor, where the proximity sensor is configured with an emitter and a receiver that respectively emits and receives the infrared light. The emitter and receiver are arranged on one side of the display panel in parallel. Such configuration causes the following issues: 1. the screen-to-body ratio of the front side of the electronic device is not sufficiently large due to the parallel arrangement of the emitter and receiver; 2. because the proximity sensor needs to emit light outwards, the front side of the electronic device needs to be configured with a hole corresponding to the proximity sensor, which damages the integrity of the front side of the electronic device.

### BRIEF SUMMARY OF THE DISCLOSURE

One aspect of the present disclosure provides an organic light-emitting diode (OLED) display panel. The OLED display panel includes a layered structure. The layered structure includes an emitter and a receiver. The emitter emits an infrared light, and the infrared light traverses a portion of the layered structure that is above the emitter, and the receiver receives the infrared light that traverses a portion of the layered structure that is above the receiver.

Another aspect of the present disclosure provides an electronic device. The electronic device includes an OLED display panel having a layered structure. The layered structure includes an emitter and a receiver. The emitter emits an infrared light, and the infrared light traverses a portion of the layered structure that is above the emitter, and the receiver receives the infrared light that traverses a portion of the layered structure that is above the receiver.

Other aspects of the present disclosure can be understood by those skilled in the art in light of the description, the claims, and the drawings of the present disclosure.

### BRIEF DESCRIPTION OF THE DRAWINGS

In order to more clearly illustrate technical solutions in embodiments of the present disclosure, drawings for describing the embodiments are briefly introduced below. Obviously, the drawings described hereinafter are only some embodiments of the present disclosure, and it is possible for those ordinarily skilled in the art to derive other drawings from such drawings without creative effort.

FIG. 1 illustrates a structural schematic view of an example of an organic light-emitting diode (OLED) display panel in accordance with some embodiments of the present disclosure; and

FIG. 2 illustrates a structural schematic view of an example of an electronic device in accordance with some embodiments of the present disclosure.

In the accompanying drawings: 1—infrared light-emitting unit; 2—RGB organic light-emitting layer; 3—red light-emitting unit; 4—green light-emitting unit; 5—blue light-emitting unit; 6—receiver; 7—anode layer; 8—cathode layer; 9—thin-film transistor; 10—glass substrate; 11—polarization plate; 12—encapsulation cover; 200—OLED display panel.

### DETAILED DESCRIPTION

Various solutions and features of the present disclosure will be described hereinafter with reference to the accompanying drawings. It should be understood that, various modifications may be made to the embodiments described below. Thus, the specification shall not be construed as limiting, but is to provide examples of the disclosed embodiments. Further, in the specification, descriptions of well-known structures and technologies are omitted to avoid obscuring concepts of the present disclosure.

The terminology used herein is for the purpose of describing specific embodiments and is not intended to be limiting of the present disclosure. As used herein, the singular forms “a,” “an,” and “the” are intended to include the plural forms as well, unless the context clearly indicates otherwise. Further, the terms “include,” “including,” “comprise,” and “comprising” specify the present of the stated features, steps, operations, components and/or portions thereof, but do not exclude the possibility of the existence or adding one or more other features, steps, operations, components, and/or portions thereof.

As used herein, the term “and/or” includes any and all combinations of one or more of the associated listed items. Expression such as “at least one of” when preceding a list of elements may modify the entire list of elements and may not modify the individual elements of the list.

Unless otherwise defined, all terms including technical and scientific terms used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The present disclosure provides an organic light-emitting diode (OLED) display panel. The OLED display panel includes an emitter and a receiver. The emitter is disposed in a layered structure of the OLED display panel and is configured to emit an infrared light, where the infrared light traverses the portion of the layered structure of the OLED display panel disposed above the emitter. The receiver is also disposed in the layered structure of the OLED display panel, and the receiver is configured to receive the infrared light that traverses the layered structure of the OLED display panel located above the receiver.

Different from the conventional configuration of a display panel in which the emitter and the receiver are disposed side-by-side on one side of the display panel, according to the disclosed OLED display panel, the emitter and the receiver are both configured in the layered structure of the OLED display panel. Accordingly, the front side of the electronic device that includes the display panel (the side of the display panel that displays images) no longer needs to be configured with a hole for the proximity sensor including the emitter and receiver, which ensures the integrity of the front side of the electronic device. Further, the front side of the electronic device may realize full-screen display, and the screen-to-body ratio of the display panel may be increased, thus improving the user experience.

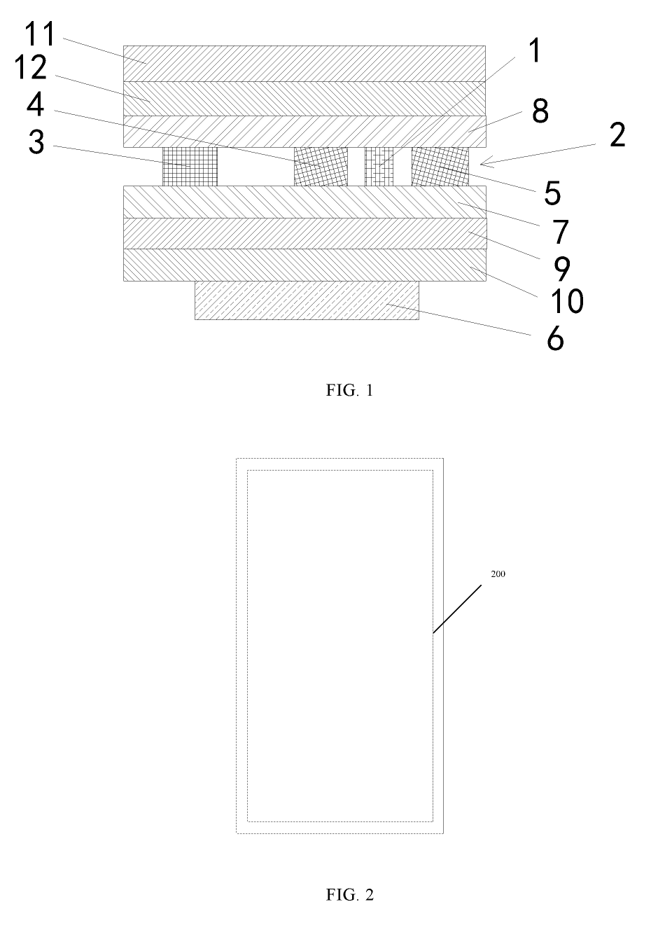

FIG. 1 illustrates a structural schematic view of an example of an organic light-emitting diode (OLED) display panel in accordance with some embodiments of the present disclosure. As shown in FIG. 1, the OLED display panel includes a layered structure. The layered structure of the OLED display panel may include an emitter 1, a red-green-blue (RGB) organic light-emitting layer 2, and a receiver 6. The RGB organic light-emitting layer 2 may include at least one red light-emitting unit 3, at least one green light-emitting unit 4, and at least one blue light-emitting unit 5. The RGB organic light-emitting layer 2 is able to generate three primary colors, i.e., red, green, and blue, thus forming basic colors for display of colors or images or words of the display panel.

In some embodiments, as shown in FIG. 1, the layered structure further includes an anode layer 7, a cathode layer 8, a thin film transistor (TFT) layer (or a thin film transistor) 9, and a glass substrate 10. Further, in some embodiments, as shown in FIG. 1, the layered structure, for example, includes a polarization plate 11 and an encapsulation cover 12.

The emitter 1 may be, for example, an infrared light-emitting unit 1. In other words, the infrared light-emitting unit may function as the emitter. The infrared light-emitting unit 1 may be disposed in the RGB organic light-emitting layer 2, i.e., belong to the RGB organic light-emitting layer 2.

The infrared light-emitting unit 1 may include an organic material that is able to emit infrared light, and the infrared light emitted by the infrared light-emitting unit 1 may traverse the portion of the layered structure of the OLED display panel that is above the infrared light-emitting unit 1. When a human face or another object gets closer to the OLED display panel, the infrared light may be reflected, and the receiver 6 may determine a distance based on the reflected infrared light.

For example, when the human face is relatively close to the OLED display panel, the receiver 6 may receive the reflected infrared light, and transmit a signal to a controller to automatically power off the OLED display panel. When the human face is relatively far from the OLED display panel, the receiver 6 may not receive the reflected infrared light, and the OLED display panel may remain in a responsive state.

In some embodiments, the RGB organic light-emitting layer 2 may include a plurality of red light-emitting units 3, a plurality of green light-emitting units 4, and a plurality of blue light-emitting units 5. The infrared light-emitting unit 1 may be disposed in a gap between any two light-emitting units from the plurality of red light-emitting units 3, the plurality of green light-emitting units 4, and the plurality of blue light-emitting units 5.

Referring to FIG. 1, light-emitting units of the RGB organic light-emitting layer 2 may include a red light-emitting unit 3, a green light-emitting unit 4, and a blue light-emitting unit 5 sequentially. The infrared light-emitting unit 1 may be disposed between the green light-emitting unit 4 and the blue light-emitting unit 5, or between the red light-emitting unit 3 and the green light-emitting unit 4.

In some embodiments, the layered structure of the OLED display panel may include a plurality of emitters 1. For example, the layered structure of the OLED display panel may include two infrared light-emitting units 1 (i.e., the emitters 1), and the two infrared light-emitting units 1 may be disposed between the red light-emitting unit 3 and the green light-emitting unit 4, and between the green light-emitting unit 4 and the blue light-emitting unit 5, respectively. That is, the positions and numbers of the infrared light-emitting units may be configured based on specific situations.

In another embodiment, a pixel may include the red light-emitting unit 3, the green light-emitting unit 4, and the blue light-emitting unit 5. The infrared light-emitting unit 1 may be disposed in a gap between different pixels. For example, the infrared light-emitting unit 1 may be disposed between the red light-emitting unit 3 of a pixel and the green light-emitting unit 4 of another pixel, or between the red light-emitting unit 3 of a pixel and the blue light-emitting unit 5 of another pixel, or between the green light-emitting unit 4 of a pixel and the blue light-emitting unit 5 of another pixel.

Further, as shown in FIG. 1, the infrared light-emitting unit 1 may be located in a gap of the RGB organic light-emitting layer 2 that is close to an edge of the OLED display panel. For example, the area of the RGB organic light-emitting layer 2 that is close to the edge of the OLED display panel may not be configured with the red light-emitting unit 3, or the green light-emitting unit 4, or the blue light-emitting unit 5, or a pixel including the red light-emitting unit 3, the green light-emitting unit 4 and the blue light-emitting unit 5. Thus, the infrared light-emitting unit 1 may be configured in a gap of the RGB organic light-emitting layer 2 that is close to the edge of the OLED display panel to emit infrared light. Accordingly, whether a human face or other objects approaches the OLED display panel can be more accurately detected.

In one embodiment, a plurality of infrared light-emitting units 1 may be distributed in a plurality of gaps of the RGB organic light-emitting layer 2 to detect, from all orientations of the front side of the OLED display panel, whether a human face or other objects approaches the display panel. The plurality of gaps may include one or more gaps of the RGB organic light-emitting layer 2 that are close to the edge of the OLED display panel, and gaps between any two light-emitting units from the plurality of red light-emitting units 3, the plurality of green light-emitting units 4, and the plurality of blue light-emitting units 5.

Further, the OLED display panel may further include one or more infrared transmission filtering units (not shown), and the infrared transmission filtering units may be disposed corresponding to the infrared light-emitting units 1 in one-to-one correspondence. The infrared transmission filtering unit may be configured to block the red light, the green light, and/or the blue light around the infrared light-emitting unit 1, while allowing the infrared light to be emitted. The infrared transmission filtering unit may also be disposed in the layered structure of the OLED display panel.

In one embodiment, as shown in FIG. 1, the layered structure of the OLED display panel includes the anode layer 7 and the cathode layer 8, and the anode layer 7 and the cathode layer 8 are disposed on two sides of the RGB organic light-emitting layer 2. For example, the anode layer 7 may be disposed below the RGB organic light-emitting layer 2, and the cathode layer 8 may be disposed above the RGB organic light-emitting layer 2.

In some embodiments, the thin-film transistor layer 9 of the OLED display panel may be a thin-film transistor 9 or include a plurality of thin-film transistors. When the thin-film transistor 9 of the OLED display panel, such as a low-temperature-polycrystalline silicon thin film transistor (LTPS-TFT), is switched on (i.e., becoming conducting), holes from the anode layer 7 and electrons from the cathode layer 8 may recombine at the infrared light-emitting unit 1, and the infrared light-emitting unit 1 may be excited to emit the infrared light.

The light-emitting principles of the red light-emitting unit 3, the green light-emitting unit 4, and the blue light-emitting unit 5 of the RGB organic light-emitting layer 2 are similar to that of the infrared light-emitting layer 1. By controlling the current passing through the thin film transistor 9, the degrees of brightness of the red light-emitting unit 3, the green light-emitting unit 4, and the blue light-emitting unit 5 may be controlled, thereby mixing out a desired color.

The cathode layer 8 may be a transparent cathode layer, and the transparent cathode layer may be configured to allow the infrared light, red light, green light, and blue light emitted by the red light-emitting unit 3, the green light-emitting unit 4, and the blue light-emitting unit 5 to traverse therethrough. In other embodiments, the anode layer 7 may be configured to be a transparent anode layer, and under such situation, the configuration location of the transparent anode layer and the cathode layer may be switched with respect to the configuration shown in FIG. 1. That is, the transparent anode layer may be configured above the RGB organic light-emitting layer 2, and the cathode may be configured below the RGB organic light-emitting layer 2.

In some other embodiments, the anode layer 7 and the cathode layer 8 may be configured to be a transparent anode layer and a transparent cathode layer, respectively. Under this situation, the positions of the transparent anode layer and the transparent cathode layer may be exchangeable. That is, the transparent anode layer may be disposed above or below the RGB organic light-emitting layer 2, and the transparent cathode layer may correspondingly be disposed below or above the RGBB organic light-emitting layer 2.

In the foregoing examples of the configuration positions of the anode layer 7 and the cathode layer 8, the thin film transistor 9 may be configured below the anode layer 7 (or the cathode layer 8) below the RGB organic light-emitting layer 2. Thus, the infrared light-emitting unit 1, the red light-emitting unit 3, the green light-emitting unit 4, and the blue light-emitting unit 5 may emit the infrared light, red light, the green light, or the blue light, respectively, without the emission of the infrared light, red light, green light, or blue light being blocked.

In some embodiments, the infrared transmittance filtering units configured corresponding to the infrared light-emitting units 1 in the one-to-one correspondence may be configured above the cathode layer 8 (or the anode layer 7) above the RGB organic light-emitting layer 2.

Further, a glass substrate 10 may be disposed below the thin film transistor 9 for feasible configuration of the receiver 6. The receiver 6 may be attached below the glass substrate 10 through an optically clear adhesive (OCA). The receiver 6 may be configured to correspond to all infrared light-emitting units 1 to conveniently receive the reflected infrared light. In some embodiments, the receiver 6 may be configured on a side surface of the layered structure of the OLED display panel, as long as the receiver 6 can receive the infrared light.

In some embodiments, as shown in FIG. 1, the OLED display panel further includes the polarization plate 11 and the encapsulation cover 12. The polarization plate 11 and the encapsulation 12 may be attached to the infrared transmittance filtering units through an OCA. The infrared transmittance filtering units, the cathode layer 8, the RGB organic light-emitting layer 2, the anode layer 7, and the thin film transistor 9 of the OLED display panel may be formed via a sputtering technique to obtain the layered structure of the OLED display panel. The thickness of the infrared light-emitting unit 1 on the anode layer 7 or the cathode layer 8 may be approximately 1 nm˜10 nm. The infrared light-emitting unit 1 may also be sputtered on the anode layer 7.

The present disclosure further provides an electronic device. FIG. 2 illustrates a structural schematic view of an example of an electronic device in accordance with some embodiments of the present disclosure. As shown in FIG. 2, the electronic device includes an OLED display panel 200. A display output region of the OLED display panel 200 is exposed through a first surface of the electronic device. The electronic device may be, for example, a cellphone, a tablet, or a smart TV. The OLED display panel 200 may be any OLED display panel consistent with the disclosure, such as the OLED display panel shown in FIG. 1 and described above.

Similar to the OLED display panel described above, the OLED display panel 200 may include an emitter and a receiver configured in a layered structure of the OLED display panel 200. The emitter is configured to emit an infrared light, where the infrared light traverses the portion of the layered structure of the OLED display panel 200 disposed above the emitter to be emitted from the display output region. The receiver is configured to receive the infrared light that traverses the portion of the layered structure of the OLED display panel located above the receiver. Thus, the first surface of the electronic device no longer needs to include a hole for a sensor including the emitter and the receiver.

In the disclosed OLED display panel, the emitter and the receiver are both configured in the layered structure of the OLED display panel. Accordingly, the front side of the electronic device (the side of the display panel that displays images) no longer needs to include a hole for the proximity sensor (P-sensor) including the emitter and receiver, which ensures the integrity of the front side of the electronic device. Further, the front side of the electronic device may realize full-screen display, and the screen-to-body ratio of the screen may be increased, thus improving the user experience.

In one embodiment, the OLED display panel 200 includes a structure shown in FIG. 1, in which the emitter is the infrared light-emitting unit 1, and the layered structure of the OLED display panel includes an RGB organic light-emitting layer 2. The infrared light-emitting unit 1 functioning as the emitter belongs to the RGB organic light-emitting layer 2.

Further, the RGB organic light-emitting layer 2 includes a plurality of red light-emitting units 3, a plurality of green light-emitting units 4, and a plurality of blue light-emitting units 5. In some embodiments, the infrared light-emitting unit 1 may be disposed in the gap between any two light-emitting units from the plurality of red light-emitting units 3, the plurality of green light-emitting units 4, and the plurality of blue light-emitting units 5. In some other embodiments, the infrared light-emitting unit 1 may be located in a gap of the RGB organic light-emitting layer 2 that is close to an edge of the OLED display panel.

Further, the OLED display panel may include one or more infrared transmission filtering units, and the infrared transmission filtering units may be configured corresponding to the infrared light-emitting units 1 in one-to-one correspondence. The infrared transmission filtering unit may be configured to block the red light, the green light, and/or blue light around the infrared light-emitting unit 1.

Further, in some embodiments, the layered structure of the OLED display panel includes an anode layer 7 and a cathode layer 8 disposed on two sides of the RGB organic light-emitting layer 2. When a thin-film transistor 9 of the OLED display panel is switched on, the holes from the anode layer 7 and the electrons from the cathode layer 8 may recombine at the infrared light-emitting unit 1, and the infrared light-emitting unit 1 may be excited to emit infrared light.

As such, different from the existing technologies, which requires forming a hole for the P-sensor in the front glass cover and hence cannot realize full-screen display, the present disclosure places the emitter and the receiver of the P-sensor in the layered structure of the OLED display panel. Thus, no hole needs to be configured in the glass cover, thus ensuring a maximal screen-to-body ratio.

The foregoing embodiments are merely examples of embodiments of the present disclosure, and are not intended to limit the present disclosure. The scope of the invention is defined by the appended claims. Without departing from the spirit and scope of the present disclosure, those skilled in the relevant art can make various modifications or equivalent replacements to the present disclosure. Such modifications or equivalent replacements shall all fall within the scope of the present disclosure.

What is claimed is:

1. An organic light-emitting diode (OLED) display panel comprising:
a layered structure including:
an emitter, wherein the emitter emits an infrared light, and the infrared light traverses a portion of the layered structure that is above the emitter; and
a receiver, wherein the receiver receives the infrared light that traverses a portion of the layered structure that is above the receiver.

2. The OLED display panel according to claim 1, wherein:
the layered structure includes a red-green-blue (RGB) organic light-emitting layer, and
the emitter includes an infrared light emitting unit disposed in the RGB organic light-emitting layer.

3. The OLED display panel according to claim 2, wherein:
the RGB organic light-emitting layer includes a plurality of red light-emitting units, a plurality of green light-emitting units, and a plurality of blue light-emitting units, and
the infrared light-emitting unit is disposed in a gap between any two of the plurality of red light-emitting units, the plurality of green light-emitting units, and the plurality of blue light-emitting units.

4. The OLED display panel according to claim 3, wherein:
the infrared light-emitting unit is located in a gap of the RGB organic light-emitting layer that is close to an edge of the OLED display panel.

5. The OLED display panel according to claim 2, further comprising:
an infrared transmission filtering unit arranged corresponding to the light-emitting unit, wherein the infrared transmission filtering unit blocks red light, green light, and blue light around the infrared light-emitting unit.

6. The OLED display panel according to claim 2, wherein:
the layered structure further includes:
an anode layer and a cathode layer disposed on two sides of the RGB organic light-emitting layer; and
one or more thin film transistors, and
in response to the one or more thin film transistors being turned on, holes from the anode layer and electrons from the cathode layer recombine at the infrared light-emitting unit to emit infrared light.

7. The OLED display panel according to claim 6, wherein:
the one or more thin film transistors are disposed below the RGB organic light-emitting layer.

8. An electronic device comprising:
an organic light-emitting diode (OLED) display panel having a layered structure,
wherein:
a display output region of the OLED display panel is exposed through a front surface of the electronic device, and
the layered structure includes:
an emitter, wherein the emitter emits an infrared light, and the infrared light traverses a portion of the layered structure that is above the emitter; and
a receiver, wherein the receiver receives the infrared light that has traversed a portion of the layered structure that is above the receiver.

9. The electronic device according to claim 8, wherein:
the layered structure includes a red-green-blue (RGB) organic light-emitting layer, and
the emitter includes an infrared light emitting unit disposed in the RGB organic light-emitting layer.

10. The electronic device according to claim 9, wherein:
the RGB organic light-emitting layer includes a plurality of red light-emitting units, a plurality of green light-emitting units, and a plurality of blue light-emitting units, and
the infrared light-emitting unit is disposed in a gap between any two of the plurality of red light-emitting units, the plurality of green light-emitting units, and the plurality of blue light-emitting units.

11. The electronic device according to claim 10, wherein:
the infrared light-emitting unit is located in a gap of the RGB organic light-emitting layer that is close to an edge of the OLED display panel.

12. The electronic device according to claim 9, wherein the OLED display panel further includes:
an infrared transmission filtering unit arranged corresponding to the light-emitting unit,
wherein the infrared transmission filtering unit blocks red light, green light, and blue light around the infrared light-emitting unit.

13. The electronic device according to claim 9, wherein:
the layered structure further includes:
an anode layer and a cathode layer disposed on two sides of the RGB organic light-emitting layer; and
one or more thin film transistors, and
in response to the one or more thin film transistors being turned on, holes from the anode layer and electrons from the cathode layer recombine at the infrared light-emitting unit to emit infrared light.

14. The electronic device according to claim 13, wherein:
the one or more thin film transistors are disposed below the RGB organic light-emitting layer.
